(19) United States
(12) Patent Application Publication
(10) Pub. No.: US 2017/0179425 A1
(43) Pub. Date: Jun. 22, 2017

(54) PACKAGE SUBSTRATE AND MANUFACTURING METHOD THEREOF, AND OLED DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Wei QUAN, Beijing (CN); Chia Hao CHANG, Beijing (CN)

(73) Assignees: BOE TECHNOLOGY GROUP CO., LTD., Beijing (CN); HEFEI XINSHENG OPTOELECTRONICS TECHNOLOGY CO., LTD., Hefei, Anhui (CN)

(21) Appl. No.: 15/129,739

(22) PCT Filed: Nov. 17, 2015
(86) PCT No.: PCT/CN2015/094758

§ 371 Date: Sep. 27, 2016

(30) Foreign Application Priority Data
Nov. 17, 2014 (CN) 201410652846.3

(51) Int. Cl. H01L 51/52; H01L 51/56

(52) U.S. Cl. CPC H01L 51/5246; H01L 51/56

(57) ABSTRACT

Embodiments of the present invention provide a package substrate and a manufacturing method thereof. The package substrate (10) comprises a central region (10a) used for being coated with filler adhesive, and a peripheral region (10b) used for being coated with sealant. Surface of the peripheral region (10b) at corners thereof includes concave-convex structures (101). The present invention further provides an OLED display device comprising the package substrate (10).

### FIELD OF THE INVENTION

The present invention relates to the field of display technology, and particularly relates to a package substrate and a manufacturing method thereof, and an OLED display device comprising the package substrate.

### BACKGROUND OF THE INVENTION

Due to the advantages of self-illumination, high brightness, fast response speed, light weight and thinness, full color and no parallax, organic light emitting display (OLED) devices have been applied in display field.

An organic material functional layer in an OLED device is particularly sensitive to water vapor and oxygen. If intrusion of water and oxygen occurs, it is very likely to cause dark spots in a light-emitting region, which will result in display fault and affect service life of the display device.

With respect to an OLED device formed on a glass substrate, glass package is mainly adopted in the prior art. For example, after an OLED device is formed on a base substrate, a package substrate may be provided on the OLED device to cover the OLED device, and the base substrate and the package substrate are bonded together through water-resistant sealant applied at edges of the base substrate and the package substrate, so as to prevent water vapor and oxygen from damaging the OLED device.

In a dam & filler process, a peripheral region of a package substrate is coated with sealant and a central region of the package substrate is coated with filler adhesive, and then the package substrate and a base substrate provided with an OLED device are laminated together and cured so as to finish the package. As shown in FIG. 1, in the process of applying the sealant, a sealant line 100 is likely to become thinner at a corner of a package substrate 10, which will lead to easy intrusion of water and oxygen and thus influence package effect of the device.

### SUMMARY OF THE INVENTION

The embodiments of the present invention provide a package substrate and a manufacturing method thereof, and an OLED display device comprising the package substrate, which prevent intrusion of water and oxygen by increasing a contact area between sealant and the substrate, so as to improve package effect.

According to one aspect of the present invention, there is provided a package substrate, comprising a central region used for being coated with filler adhesive, and a peripheral region used for being coated with sealant. Surface of the peripheral region at corners thereof includes concave-convex structures.

The concave-convex structure at the corner may be in an L-like shape.

A groove may be provided at a predetermined position in the peripheral region of the package substrate. The predetermined position is a position where the sealant starts to be applied.

A cross section shape of the groove may be hemispherical.

The package substrate may be a glass substrate.

According to another aspect of the present invention, there is provided an OLED display device, comprising a base substrate and the package substrate according to the present invention, and an OLED device located therebetween.

According to another aspect of the present invention, there is provided a manufacturing method of a package substrate, the package substrate comprising a central region used for being coated with filler adhesive, and a peripheral region used for being coated with sealant, wherein, the method comprises processing corners of the peripheral region to form concave-convex structures.

Mechanical grinding or chemical etching may be adopted to process the corners of the peripheral region so as to form the concave-convex structures.

The method may further comprise forming a groove at a predetermined position in the peripheral region of the package substrate. The predetermined position is a position where the sealant starts to be applied.

The groove may be formed by etching the predetermined position on the package substrate.

According to the embodiments of the present invention, by providing the concave-convex structures at the corners of the package substrate, frosted surfaces are formed at the corners of the package substrate, so that a contact area between the sealant and the package substrate can be effectively increased after the package substrate and the base substrate are laminated together, and intrusion of water and oxygen is prevented, thereby improving package effect of the OLED device.

### BRIEF DESCRIPTION OF THE DRAWINGS

In order to illustrate the technical solutions of embodiments of the present invention more clearly, the embodiments of the present invention will be further described in detail below with reference to the accompanying drawings. It should be understood that the following description is provided merely for the purpose of illustrating the embodiments of the present invention, rather than limiting the scope of the present invention. Those of ordinary skill in the art can make various variations and improvements to the embodiments without departing from the scope of the present invention. In the drawings:

FIG. 1 is a schematic diagram illustrating distribution of a sealant line at a corner of a package substrate in the prior art;

FIG. 2 is a schematic structural diagram of a package substrate according to an embodiment of the present invention;

FIG. 3 is a schematic structural diagram of a package substrate according to another embodiment of the present invention;

FIG. 4 is a schematic structural diagram of a package substrate according to another embodiment of the present invention;

FIG. 5 is a schematic structural diagram of a package substrate according to another embodiment of the present invention;

FIG. 6 is a schematic diagram illustrating a process of applying sealant according to the embodiments of the present invention;

FIGS. 7A to 7C are schematic diagrams illustrating various cross section shapes of a groove in a peripheral region of the package substrate according to the embodiments of the present invention;

FIG. 8 is a schematic diagram of an OLED display device according to the embodiments of the present invention; and

FIG. 9 is an effect diagram of a frosting process on a package substrate according to the embodiments of the present invention.

### DETAILED DESCRIPTION OF THE EMBODIMENTS

Embodiments of the present invention will be described clearly and completely below with reference to the accompanying drawings. However, the described embodiments are just for illustration, but not intended to limit the scope of the present invention.

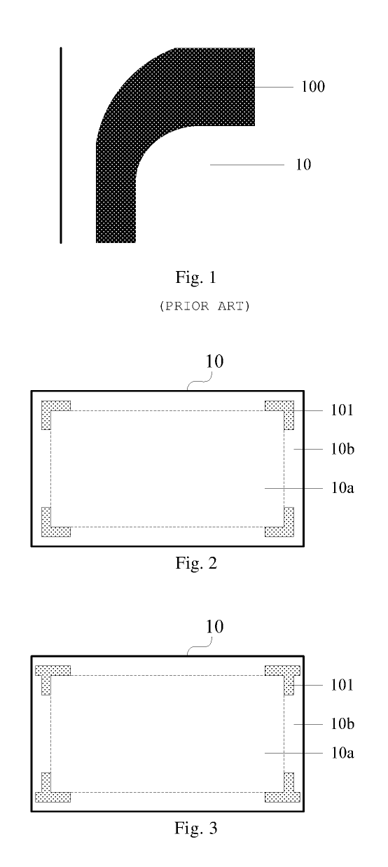

FIGS. 2-4 are schematic structural diagrams of package substrates according to the embodiments of the present invention.

With reference to FIGS. 2-4, a package substrate 10 according to the embodiments of the present invention comprises a central region 10a used for being coated with filler adhesive, and a peripheral region 10b used for being coated with sealant. Surface of the peripheral region 10b at each corner thereof includes a concave-convex structure 101.

The package substrate 10 can be used for packaging an OLED device. According to different light exiting directions of OLED devices, the package substrate 10 may be a transparent substrate (e.g. a glass substrate) or an opaque substrate (e.g. a metal substrate).

In a process of coating the peripheral region 10b of the package substrate 10 with the sealant, sealant lines usually become too thin at corners of the package substrate 10, which will result in decreased capability of blocking water and oxygen at the corners. In the embodiments of the present invention, by providing the concave-convex structures 101 at the corners, frosted surfaces with certain roughness are formed so as to effectively increase a contact area between the sealant and the package substrate 10, thereby enhancing the capability of blocking water and oxygen.

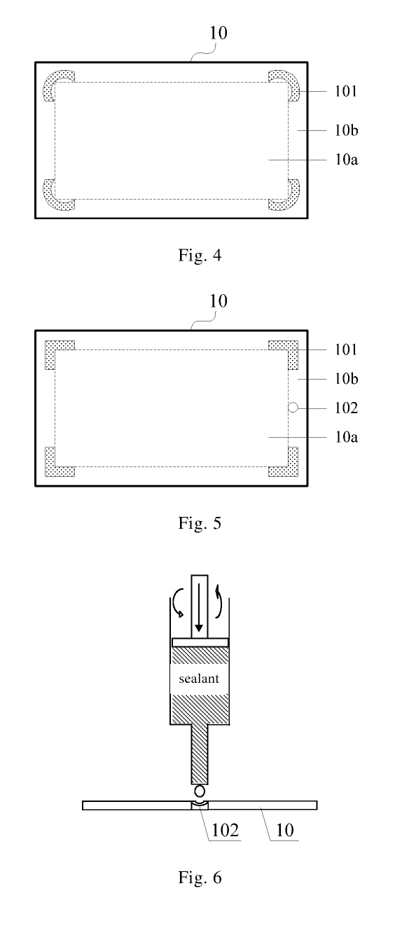

The concave-convex structures 101 are used for forming the frosted surfaces with certain roughness, and a shape of the region where the frosted surface is formed is not limited in the present invention, and may be any one of an L-like shape (as shown in FIG. 2), a T-like shape (as shown in FIG. 3) and an arc shape (as shown in FIG. 4), or any other irregular shape.

By providing the concave-convex structures 101 on the surface of the package substrate 10 at the corners thereof, the frosted surfaces can be formed by the concave-convex structures 101, so that a contact area between the sealant and the package substrate 10 can be effectively increased after the package substrate and a base substrate are laminated together, and intrusion of water and oxygen is prevented, thereby improving package effect of an OLED device.

As shown in FIG. 2, the concave-convex structure 101 at the corner may be in an L-like shape, that is, the shape of the frosted surface formed by the concave-convex structure 101 may be an L-like shape.

In general, the package substrate 10 is a rectangular substrate. By providing an L-shaped frosted surface at each corner of the rectangular substrate, it can be ensured that a track of applying the sealant is consistent with the shape of the frosted surface in the process of applying the sealant, so that a contact area between the sealant and the package substrate 10 can be effectively increased after the lamination.

In addition, the shape of the frosted surface formed by the concave-convex structure 101 may be other shape, and is not particularly limited in the present invention.

FIG. 5 is a schematic structural diagram of a package substrate according to another embodiment of the present invention, and FIG. 6 is a schematic diagram illustrating a process of applying sealant according to the embodiments of the present invention.

As shown in FIG. 5, a groove 102 is provided at a predetermined position in the peripheral region 10b of the package substrate 10. The predetermined position is a position where the sealant starts to be applied.

As shown in FIG. 6, because overflow of the sealant usually happens at the position where the sealant starts to be applied due to instability of equipment, the sealant line is very likely to become too wide after the lamination. The entire structure of an electronic device will be adversely affected if the sealant spreads into surrounding circuit regions.

By forming the groove 102 at the position where the sealant starts to be applied, a storage space for excessive sealant can be provided, so as to avoid too wide sealant line resulting from overflow of sealant, thereby reducing the effect on circuits of the device.

The groove 102 is provided on the track of applying the sealant, and may be specifically provided in the region where the frosted surface is formed or in the region where no frosted surface is formed on the package substrate 10. Because the frosted surface is formed by the concave-convex structure 101, the structure and shape of the frosted surface may be affected to a certain extent if the groove 102 is provided in the region where the frosted surface is formed. As a result, the groove 102 is preferably provided in the region without frosted surface on the track of applying the sealant.

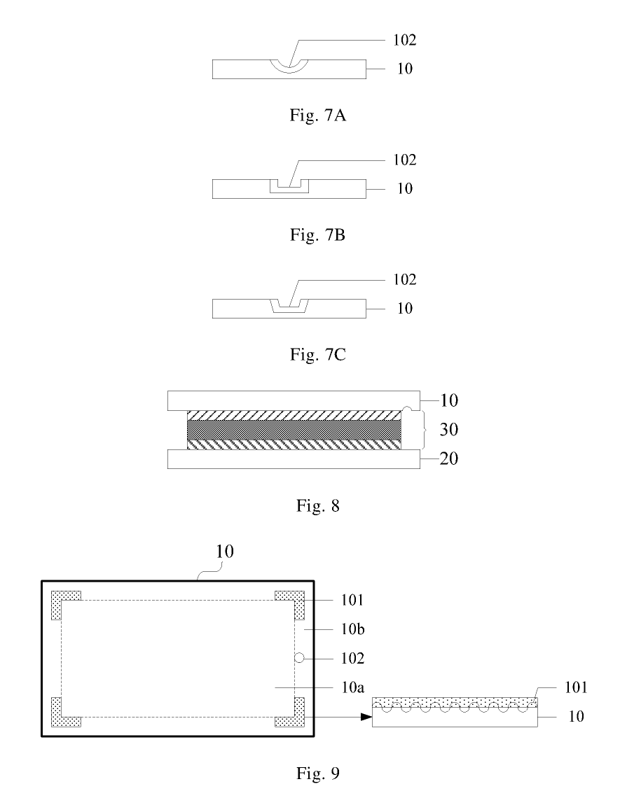

FIGS. 7A to 7C are schematic diagrams of various cross section shapes of the groove in the peripheral region of the package substrate according to the embodiments of the present invention.

As shown in FIGS. 7A to 7C, the cross section shape of the groove 102 may be a hemispherical shape, a shape of truncated pyramid, a cylindrical shape, or any other irregular shape.

The groove 102 is mainly used for accommodating excessive sealant applied during initial coating, and a drop of the sealant is in an approximately spherical shape, so the groove 102 having a hemispherical cross section shape can match the shape of the drop of the sealant best, which will facilitate spreading of the drop of the sealant in the groove 102 and also avoid forming bubbles. Therefore, the cross section shape of the groove 102 is preferably hemispherical.

According to the embodiments of the present invention, the package substrate 10 may be any one of a glass substrate, a sapphire substrate, a silicon substrate and a metal substrate. Whether the package substrate 10 needs to be light-transmissive or not can be determined according to a light exiting direction of an OLED device.

FIG. 8 is a schematic diagram of an OLED display device according to the embodiments of the present invention.

As shown in FIG. 8, an OLED display device according to the embodiments of the present invention comprises a base substrate 20, a package substrate 10, and an OLED device 30 located therebetween. The OLED device may comprise an anode, a cathode, and an organic material functional layer located therebetween.

The base substrate 20 and the package substrate 10 each may be any one of a glass substrate, a sapphire substrate, a silicon substrate and a metal substrate. Whether the package substrate 10 or the base substrate 20 needs to be light-transmissive or not can be determined according to a light exiting direction of the OLED device.

When the package substrate 10 according to the embodiments of the present invention is used to package the OLED device 30 formed on the base substrate 20, a peripheral region 10b of the package substrate 10 may be coated with sealant and a central region 10a of the package substrate 10 may be coated with filler adhesive, and then the package substrate 10 and the base substrate 20 are laminated together and cured.

A groove 102 is provided at a predetermined position of the package substrate 10, so that a certain storage space for excessive sealant formed during the initial coating can be provided, which avoids too wide sealant line after the lamination. In addition, concave-convex structures 101 are provided at corners of the package substrate 10 to form frosted surfaces at the corners of the package substrate 10, so that a contact area between the package substrate 10 and the sealant can be effectively increased after the package substrate 10 and the base substrate 20 are laminated together, and intrusion of water and oxygen is prevented, thereby significantly improving package effect of the OLED device and prolonging the service life thereof.

FIG. 9 is an effect diagram of a frosting process on a package substrate according to the embodiments of the present invention.

As shown in FIG. 9, a manufacturing method of a package substrate according to the embodiments of the present invention comprises processing corners of a peripheral region of a package substrate to form concave-convex structures 101.

Mechanical grinding or chemical etching may be adopted to process the corners of the peripheral region of the package substrate so as to form the concave-convex structures 101.

By taking a case that a glass substrate serves as the package substrate as an example, exemplary description of the processing will be given below. Abrasives such as emery, silica sand and pomegranate powder can be used to perform mechanical grinding or manual grinding on a surface of the glass substrate, so as to form a uniform rough surface. Alternatively, an etching liquid (e.g. hydrofluoric acid) can be used to process the glass substrate so as to obtain a frosted surface similar to frosted glass.

The method of processing the package substrate is not limited thereto, and other methods may be used to process the package substrate according to the material thereof, so as to obtain a frosted surface similar to frosted glass.

The manufacturing method of a package substrate according to the embodiments of the present invention may further comprise forming a groove 102 at a predetermined position in the peripheral region 10b of the package substrate 10. The predetermined position may be a position where the sealant starts to be applied.

The groove 102 may be formed by etching the predetermined position on the package substrate 10.

An etching liquid matching the material of the package substrate 10 may be used to etch the package substrate 10.

For example, in the case that the package substrate 10 is a glass substrate, hydrofluoric acid can be used to etch the glass substrate so as to form the groove 102. In the case that the package substrate 10 is a metal substrate, dilute sulfuric acid can be used to etch the metal substrate so as to form the groove 102.

By forming the groove 102 at the position where the sealant starts to be applied, a certain storage space for excessive sealant formed initially can be provided, so as to avoid too wide sealant line due to the excessive sealant, thereby reducing the effect on circuits of the device.

A cross section shape of the groove 102 is preferably hemispherical. On the one hand, the cross section shape of the groove 102 formed by an etching liquid matches the shape of a drop of the etching liquid, so it is relatively easy to form the groove 102 having a hemispherical cross section shape. On the other hand, the groove 102 having a hemispherical cross section shape will facilitate spreading of a drop of sealant in the groove, and also avoid forming bubbles.

The above merely describes the specific implementations of the present invention, but the protection scope of the present invention is not limited thereto. According to the novel teaching of the present invention, any person skilled in the art may readily envisage various variations and/substitutions, and all of these variations and/substitutions of the embodiments of the present invention shall be considered to fall into the protection scope of the present invention. Therefore, the protection scope of the present invention shall be subject to the protection scope of the claims.

1. A package substrate, comprising a central region used for being coated with filler adhesive, and a peripheral region used for being coated with sealant,
wherein, surface of the peripheral region at corners of the peripheral region includes concave-convex structures.

2. The package substrate of claim 1, wherein, the concave-convex structure at the corner is in an L-like shape.

3. The package substrate of claim 1, wherein, a groove is provided at a predetermined position in the peripheral region of the package substrate, and the predetermined position is a position where the sealant starts to be applied.

4. The package substrate of claim 3, wherein, a cross section shape of the groove is hemispherical.

5. The package substrate of claim 1, wherein, the package substrate is a glass substrate.

6. An OLED display device, comprising a base substrate, the package substrate according to claim 1, and an OLED device located between the base substrate and the package substrate.

7. A manufacturing method of a package substrate, the package substrate comprising a central region used for being coated with filler adhesive, and a peripheral region used for being coated with sealant, wherein, the method comprises:
processing corners of the peripheral region to form concave-convex structures.

8. The method of claim 7, wherein, mechanical grinding or chemical etching is adopted to process the corners of the peripheral region so as to form the concave-convex structures.

9. The method of claim 7, further comprising:
forming a groove at a predetermined position in the peripheral region of the package substrate, wherein, the predetermined position is a position where the sealant starts to be applied.

10. The method of claim 9, wherein, the groove is formed by etching the predetermined position on the package substrate.

11. The OLED display device of claim 6, wherein, the concave-convex structure at the corner is in an L-like shape.

12. The OLED display device of claim 6, wherein, a groove is provided at a predetermined position in the peripheral region of the package substrate, and the predetermined position is a position where the sealant starts to be applied.

13. The OLED display device of claim 12, wherein, a cross section shape of the groove is hemispherical.

14. The OLED display device of claim 6, wherein, the package substrate is a glass substrate.
